(19) United States
(12) Patent Application Publication
(10) Pub. No.: US 2018/0240606 A1
(43) Pub. Date: Aug. 23, 2018

(54) PEROVSKITE SOLAR CELLS INCLUDING SEMICONDUCTOR NANOMATERIALS

(71) Applicant: MASSACHUSETTS INSTITUTE OF TECHNOLOGY, Cambridge, MA (US)

(72) Inventors: Moungi G. BAWENDI, Cambridge, MA (US); Whitney R. HESS, Allston, MA (US)

(73) Assignee: Massachusetts Institute of Technology, Cambridge, MA (US)

(21) Appl. No.: 15/752,579

(22) PCT Filed: Aug. 14, 2016
(86) PCT No.: PCT/US2016/046954

§ 371 Date: Feb. 13, 2018

Related U.S. Application Data
(60) Provisional application No. 62/205,107, filed on Aug. 14, 2015.

(51) Int. Cl. H01G 9/20; H01L 51/44; H01L 51/42

(52) U.S. Cl. CPC H01G 9/2009; H01L 51/4246; H01L 51/426; H01L 51/442

(57) ABSTRACT

A photovoltaic device can include a first charge transporting layer including a plurality of semiconductor nanocrystals in contact with a first electrode, a second charge transporting layer in contact with a second electrode and an absorber layer including a perovskite material between the first charge transporting layer and the second charge transporting layer. The plurality of semiconductor nanocrystals can include a core and a shell, wherein the core has a first semiconductor material and the shell has a second semiconductor material.

### CLAIM OF PRIORITY

This application claims the benefit of prior U.S. Provisional Application No. 62/205,107, filed on August 14, 2015, which is incorporated by reference in its entirety.

### TECHNICAL FIELD

This invention relates to perovskite solar cells.

### BACKGROUND

Rapid progress has been made in the field of organic-inorganic lead halide perovskite solar cells, with the highest certified efficiency to-date reaching 20.1%. See, Yang, W. S.; Noh, J. H.; Jeon, N. J.; Kim, Y. C.; Ryu, S.; Seo, J.; Seok, S. I. Science 2015, 348 (6240), 1234-1237, which is incorporated by reference in its entirety. In order to achieve this high efficiency, blocking and mesoporous titania (TiO₂) thin-films, processed at high temperatures (up to 500° C.), are utilized as the electron transport material. In addition, similar to spiro-OMeTAD (see, Noh, J. H.; Jeon, N. J.; Choi, Y. C.; Nazeeruddin, M. K.; Grätzel M.; Seok, S. Il. J. Mater. Chem. A 2013, 1 (38), 11842, which is incorporated by reference in its entirety), the organic hole transport material (HTM), polytriarylamine, requires p-type dopants to improve charge transport properties and air exposure during the processing of this type of doped material may be problematic due to the adverse effects of humidity on the perovskite film. See, Abate, A.; Leijtens, T.; Pathak, S.; Teuscher, J.; Avolio, R.; Errico, M. E.; Kirkpatrik, J.; Ball, J. M.; Docampo, P.; McPherson, I.; Snaith, H. J. Phys. Chem. Chem. Phys. 2013, 15 (7), 2572, which is incorporated by reference in its entirety.

### SUMMARY

A photovoltaic device can include a first charge transporting layer including a plurality of semiconductor nanocrystals including a core and a shell, in contact with a first electrode, a second charge transporting layer in contact with a second electrode and an absorber layer including a perovskite material between the first charge transporting layer and the second charge transporting layer.

In certain embodiments, the first charge transporting layer can be a hole transport layer.

In certain embodiments, the perovskite material can include a lead halide perovskite.

In certain embodiments, the core can include a first semiconductor material.

In certain embodiments, the first semiconductor material can include PbS.

certain embodiments, the first semiconductor material can include ZnS, ZnSe, ZnTe, CdS, CdSe, CdTe, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbS, PbSe, PbTe, or mixtures thereof.

In certain embodiments, the shell can include a second semiconductor material.

In certain embodiments, the second semiconductor material can include CdS.

In certain embodiments, the second semiconductor material can include ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TlN, TlP, TlAs, TlSb, TlSb, PbS, PbSe, PbTe, or mixtures thereof.

In certain embodiments, the perovskite material can include a lead halide perovskite.

In certain embodiments, the perovskite material can have the formula (I)

APbX₃ (I)

where A is an organic or molecular cation and X is a halide ion.

In certain embodiments, the A can be methylammonium.

In certain embodiments, the A can be ammonium, formamidimium or phosphonium.

In certain embodiments, the A can be cesium.

In certain embodiments, the halide ion can be I⁻.

In certain embodiments, the halide ion can be Br⁻ or Cl⁻.

In certain embodiments, the second charge transporting layer can be an electron transport layer.

In certain embodiments, the electron transport layer can include [6,6]-phenyl-C₆₁-butyric acid methyl ester.

In certain embodiments, the first electrode can include indium tin oxide, gallium indium tin oxide, zinc indium tin oxide, titanium nitride, polyaniline, or combination thereof.

In certain embodiments, the device further can include a substrate in contact with the first electrode.

In certain embodiments, the substrate can include glass, plastic or metal.

A method of making a photovoltaic device can include preparing a substrate, depositing a first electrode on the substrate, depositing a first charge transporting layer including a plurality of semiconductor nanocrystals including a core and a shell in contact with a first electrode, depositing an absorber layer including a perovskite material on the first charge transporting layer, and depositing a second charge transporting layer in contact with the absorber layer.

In certain embodiments, the first charge transporting layer can be a hole transport layer.

In certain embodiments, the perovskite material can include a lead halide perovskite.

In certain embodiments, the core can include a first semiconductor material.

In certain embodiments, the first semiconductor material can include PbS.

In certain embodiments, the first semiconductor material can include ZnS, ZnSe, ZnTe, CdS, CdSe, CdTe, HgS, HgSe, HgTe, AlN, AlP, AlAs, AlSb, GaN, GaP, GaAs, GaSb, GaSe, InN, InP, InAs, InSb, TlN, TlP, TlAs, TlSb, PbS, PbSe, PbTe, or mixtures thereof.

In certain embodiments, the shell can include a second semiconductor material.

In certain embodiments, the second semiconductor material can include CdS.

In certain embodiments, the second semiconductor material can include ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TlN, TlP, TlAs, TlSb, TlSb, PbS, PbSe, PbTe, or mixtures thereof.

In certain embodiments, the perovskite material can include a lead halide perovskite.

In certain embodiments, the perovskite material can have the formula (I)

APbX₃ (I)

where A is an organic or molecular cation and X is a halide ion.

In certain embodiments, the A can be methylammonium.

In certain embodiments, the A can be ammonium, formamidimium or phosphonium.

In certain embodiments, the A can be cesium.

In certain embodiments, the halide ion can be I⁻.

In certain embodiments, the halide ion can be Br⁻ or Cl⁻.

In certain embodiments, the second charge transporting layer can be an electron transport layer.

In certain embodiments, the electron transport layer can include [6,6]-phenyl-C₆₁-butyric acid methyl ester.

In certain embodiments, the first electrode can include indium tin oxide, gallium indium tin oxide, zinc indium tin oxide, titanium nitride, polyaniline, or combination thereof.

In certain embodiments, the method can further can include depositing a second electrode.

In certain embodiments, the second electrode can include aluminum.

In certain embodiments, the substrate can include glass, plastic or metal.

Other aspects, embodiments, and features will be apparent from the following description, the drawings, and the claims.

### BRIEF DESCRIPTION OF THE DRAWINGS

FIGS. 1A-1C show device architecture and morphology characterization. FIG. 1A shows cross-sectional SEM. FIG. 1B shows schematic of the inverted device architecture in this work. FIG. 1C shows a representative planar SEM (top-view) of a MAPbI₃ film deposited onto a PbS/CdS nanocrystal film with an ITO/glass substrate.

FIG. 2 is absorbance (solid lines) and photoluminescence (dashed lines) spectra of the PbS core-only and PbS/CdS core/shell nanocrystals prepared for the Cd-OA treatment series. Spectra are normalized and offset for clarity.

FIG. 3 is absorbance (solid lines) and photoluminescence (dashed lines) spectra of the PbS core-only and PbS/CdS core/shell nanocrystals prepared for the Cd-OA treatment series. Spectra are normalized and offset for clarity.

FIG. 4 is cross-sectional SEM of an ITO/nanocrystal/MAPbI₃/PCBM/Al device utilizing a PbS/CdS core/shell nanocrystal HTM.

FIGS. 5A-5C are higher (left) and lower (right) magnification scanning electron micrographs of MAPbI₃ films deposited directly onto ITO (FIG. 5A), onto PbS core-only nanocrystals (FIG. 5B), and onto PbS/CdS core/shell nanocrystals (FIG. 5C).

FIG. 6 shows a schematic of a photovoltaic device.

### DETAILED DESCRIPTION

The highest efficiency perovskite solar cells utilize high temperature (up to 500° C.) sintered TiO₂ films High temperature processing conditions may present a limitation for some future developments in perovskite solar cells due to potentially complicated manufacturing and incompatibility with flexible substrates. This underscores the necessity for the exploration of alternative materials that are suitable for low temperature processing. A variety of organic, inorganic, and composite/bilayer charge transport materials have been explored within the framework of sub-150° C. low temperature processing. See, Docampo, P.; Ball, J. M.; Darwich, M.; Eperon, G. E.; Snaith, H. J. Nat. Commun. 2013, 4, 2761, Yang, Y; You, J.; Hong, Z.; Chen, Q.; Cai, M.; Song, T. Bin; Chen, C. C.; Lu, S.; Liu, Y; Zhou, H. ACS Nano 2014, 8 (2), 1674-1680, Malinkiewicz, 0.; Yella, A.; Lee, Y. H.; Espallargas, G. M. M.; Graetzel, M.; Nazeeruddin, M. K.; Bolink, H. J. Nat. Photonics 2014, 8 (2), 128-132, Ryu, S.; Seo, J.; Shin, S. S.; Kim, Y. C.; Jeon, N. J.; Noh, J. H.; Seok, S. Il. J. Mater. Chem. A 2015, 3 (7), 3271-3275, Wojciechowski, K.; Leijtens, T.; Siprova, S.; Schlueter, C.; Horantner, M. T.; Wang, J. T.-W.; Li, C.-Z.; Jen, A. K.-Y.; Lee, T.-L.; Snaith, H. J. J. Phys. Chem. Lett. 2015, 6 (12), 2399-2405, Li, X.; Liu, X.; Wang, X.; Zhao, L.; Jiu, T.; Fang, J. J. Mater. Chem. A 2015, 3 (29), 15024-15029, Chang, C.-Y.; Lee, K.-T.; Huang, W.-K.; Siao, H.-Y.; Chang, Y.-C. Chem. Mater. 2015, 27 (14), 5122-5130, Wang, L.; Fu, W.; Gu, Z.; Fan, C.; Yang, X.; Li, H.; Chen, H. J. Mater. Chem. C 2014, 2 (43), 9087-9090, Ye, S.; Sun, W.; Li, Y; Yan, W.; Peng, H.; Bian, Z.; Liu, Z.; Huang, C. Nano Lett. 2015, 15 (6), 3723-3728, Liu, D.; Kelly, T. L. Nat. Photonics 2013, 8 (2), 133-138, Jeng, J.-Y; Chen, K.-C.; Chiang, T.-Y; Lin, P.-Y.; Tsai, T.-D.; Chang, Y-C.; Guo, T.-F.; Chen, P.; Wen, T.-C.; Hsu, Y-J. Adv. Mater. 2014, 26 (24), 4107-4113, Yella, A.; Heiniger, L. P.; Gao, P.; Nazeeruddin, M. K.; Grätzel, M. Nano Lett. 2014, 14 (5), 2591-2596, Shin, S. S.; Yang, W. S.; Noh, J. H.; Suk, J. H.; Jeon, N. J.; Park, J. H.; Kim, J. S.; Seong, W. M.; Seok, S. Il. Nat. Commun. 2015, 6, 7410, Ke, W.; Fang, G.; Liu, Q.; Xiong, L.; Qin, P.; Tao, H.; Wang, J.; Lei, H.; Li, B.; Wan, J.; Yang, G.; Yan, Y. J. Am. Chem. Soc. 2015, 137 (21), 6730-6733, Wang, K.; Shen, P.; Li, M.; Chen, S.; Lin, M.; Chen, P.; Guo, T. ACS Appl. Mater. Interfaces 2014, 6 (15), 11851-11858, Kumar, M. H.; Yantara, N.; Dharani, S.; Graetzel, M.; Mhaisalkar, S.; Boix, P. P.; Mathews, N. Chem. Commun. 2013, 49 (94), 11089, Liu, J.; Gao, C.; Luo, L.; Ye, Y. Q.; He, X.; Ouyang, L.; Guo, X.; Zhuang, D.; Liao, C.; Mei, J.; Lau, L. W. M. J. Mater. Chem. A 2015, 3 (22), 11750-11755, Chen, W.-Y; Deng, L.-L.; Dai, S.-M.; Wang, X.; Tian, C.-B.; Zhan, X.-X.; Xie, S.-Y.; Huang, R.-B.; Zheng, L. J. Mater. Chem. A 2015, 00, 1-7, Wang, J. T. W.; Ball, J. M.; Barea, E. M.; Abate, A.; Alexander-Webber, J. a.; Huang, J.; Saliba, M.; Mora-Sero, I.; Bisquert, J.; Snaith, H. J.; Nicholas, R. J. Nano Lett. 2014, 14 (2), 724-730, Hou, F.; Su, Z.; Jin, F.; Yan, X.; Wang, L.; Zhao, H.; Zhu, J.; Chu, B.; Li, W. Nanoscale 2015, 7 (21), 9427-9432, Tao, C.; Neutzner, S.; Colella, L.; Marras, S.; Srimath Kandada, A. R.; Gandini, M.; Bastiani, M. De; Pace, G.; Manna, L.; Caironi, M.; Bertarelli, C.; Petrozza, A. Energy Environ. Sci. 2015, 8 (8), 2365-2370, and Hu, Q.; Liu, Y; Li, Y.; Ying, L.; Liu, T.; Huang, F.; Wang, S.; Huang, W.; Zhu, R.; Gong, Q. J. Mater. Chem. A 2015, 3 (36), 18483-18491, each of which is incorporated by reference in its entirety.

Previously, PbS nanocrystals have been used as a near-infrared co-sensitizer. See, Etgar, L.; Gao, P.; Qin, P.; Graetzel, M.; Nazeeruddin, M. K. J. Mater. Chem. A 2014, 2 (30), 11586, which is incorporated by reference in its entirety. Enhanced performance of sesitized solar cells with PbS/CH₃NH₃PbI₃ core/shell quantum dots have been reported. See, Seo, G.; Seo, J.; Ryu, S.; Yin, W.; Ahn, T. K.; Seok, S. Il. J. Phys. Chem. Lett. 2014, 5 (11), 2015-2020, which is incorporated by reference in its entirety. PbS nanocrystals as an inorganic HTM in regular and inverted architectures of solar cells have been reported. See Li, Y; Zhu, J.; Huang, Y; Wei, J.; Liu, F.; Shao, Z.; Hu, L.; Chen, S.; Yang, S.; Tang, J.; Yao, J.; Dai, S. Nanoscale 2015, 7 (21), 9902-9907, and Hu, L.; Wang, W.; Liu, H.; Peng, J.; Cao, H.; Shao, G.; Xia, Z.; Ma, W.; Tang, J. J. Mater. Chem. A 2015, 3 (2), 515-518, each of which is incorporatd by reference in its entirety. However, application of core/shell semiconductor nanocrystals in an inverted architecture of a perovskite solar cell has not been explored.

A photovoltaic device can include two layers separating two electrodes of the device. The material of one layer can be chosen based on the material's ability to transport holes, or the hole transporting layer (HTL). The material of the other layer can be chosen based on the material's ability to transport electrons, or the electron transporting layer (ETL). The electron transporting layer typically can include an absorber layer. When a voltage is applied and the device is illuminated, one electrode accepts holes (positive charge carriers) from the hole transporting layer, while the other electrode accepts electrons from the electron transporting layer; the holes and electrons originate as excitons in the absorptive material. The device can include an absorber layer between the HTL and the ETL. The absorber layer can include a material selected for its absorption properties, such as absorption wavelength or linewidth.

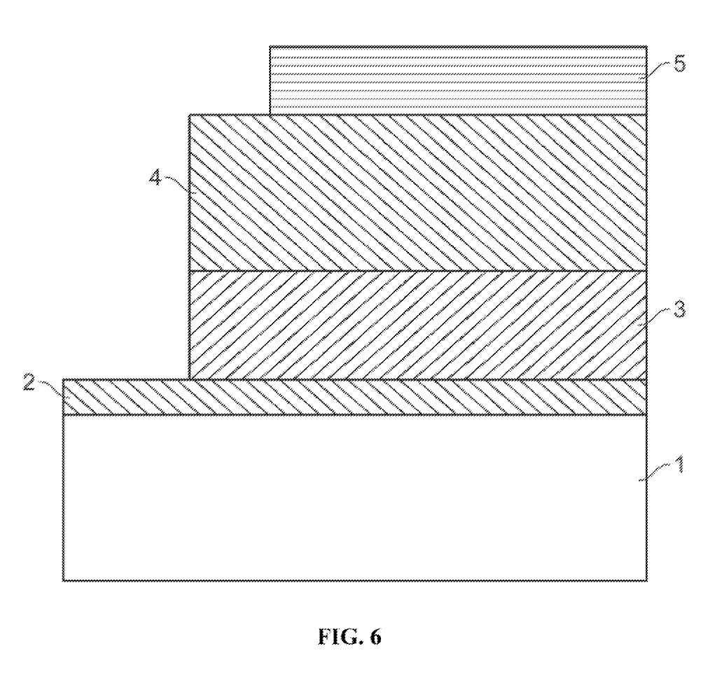

A photovoltaic device can have a structure such as shown in FIG. 6, in which a first electrode 2, a first layer 3 in contact with the electrode 2, a second layer 4 in contact with the layer 3, and a second electrode 5 in contact with the second layer 4. First layer 3 can be a hole transporting layer and second layer 4 can be an electron transporting layer. At least one layer can be non-polymeric. The layers can include an inorganic material. One of the electrodes of the structure is in contact with a substrate 1. Each electrode can contact a power supply to provide a voltage across the structure. Photocurrent can be produced by the absorber layer when a voltage of proper polarity and magnitude is applied across the device. First layer 3 can include a plurality of semiconductor nanocrystals, for example, a substantially monodisperse population of nanocrystals.

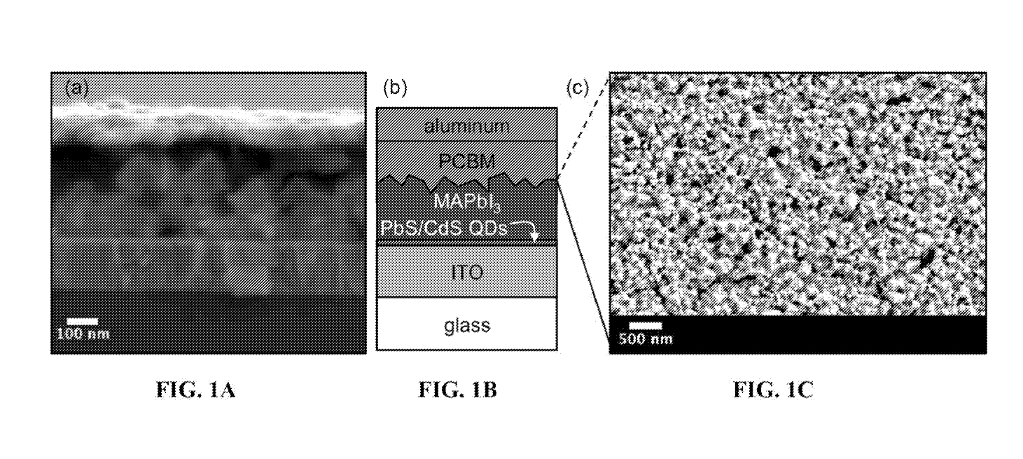

Alternatively, a separate absorber layer (not shown in FIG. 6) can be included between the hole transporting layer and the electron transporting layer. The separate absorber layer can include a perovskite material (FIG. 1B).

A hole transporting layer can include a plurality of nanocrystals. The hole transporting layer that includes nanocrystals can be a monolayer, of nanocrystals, or a multilayer of nanocrystals. In some instances, the layer including nanocrystals can be an incomplete layer, i.e., a layer having regions devoid of material such that layers adjacent to the nanocrystal layer can be in partial contact. The nanocrystals and at least one electrode have a band gap offset sufficient to transfer a charge carrier from the nanocrystals to the first electrode or the second electrode. The charge carrier can be a hole or an electron. The ability of the electrode to transfer a charge carrier permits the photoinduced current to flow in a manner that facilitates photodetection.

Photovoltaic devices including semiconductor nanocrystals can be made by spin-casting a solution containing the HTL organic semiconductor molecules and the semiconductor nanocrystals, where the HTL formed underneath of the semiconductor nanocrystal monolayer via phase separation (see, for example, U.S. patent application Ser. No. 10/400,907, filed Mar. 28, 2003, and U.S. Patent Application Publication No. 2004/0023010, each of which is incorporated by reference in its entirety). This phase separation technique reproducibly placed a monolayer of semiconductor nanocrystals between an organic semiconductor HTL and ETL, thereby effectively exploiting the favorable light absorption properties of semiconductor nanocrystals, while minimizing their impact on electrical performance. Devices made by this technique were limited by impurities in the solvent, by the necessity to use organic semiconductor molecules that are soluble in the same solvents as the semiconductor nanocrystals. The phase separation technique was unsuitable for depositing a monolayer of semiconductor nanocrystals on top of both a HTL and a HIL (due to the solvent destroying the underlying organic thin film). Nor did the phase separation method allow control of the location of semiconductor nanocrystals that emit different colors on the same substrate; nor patterning of the different color emitting nanocrystals on that same substrate.

Moreover, the organic materials used in the transport layers (i.e., hole transport, hole injection, or electron transport layers) can be less stable than the semiconductor nanocrystals used in the absorber layer. As a result, the operational life of the organic materials limits the life of the device. A device with longer-lived materials in the transport layers can be used to form a longer-lasting light emitting device.

The substrate can be opaque or transparent. A transparent substrate can be used to in the manufacture of a transparent device. See, for example, Bulovic, V. et al., Nature 1996, 380, 29; and Gu, G. et al., Appl. Phys. Lett. 1996, 68, 2606-2608, each of which is incorporated by reference in its entirety. The substrate can be rigid or flexible. The substrate can be plastic, metal or glass. The first electrode can be, for example, a high work function hole-injecting conductor, such as an indium tin oxide (ITO) layer. Other first electrode materials can include gallium indium tin oxide, zinc indium tin oxide, titanium nitride, or polyaniline. The second electrode can be, for example, a low work function (e.g., less than 4.0 eV), electron-injecting, metal, such as Al, Ba, Yb, Ca, a lithium-aluminum alloy (Li:Al), or a magnesium-silver alloy (Mg:Ag). The second electrode, such as Mg:Ag, can be covered with an opaque protective metal layer, for example, a layer of Ag for protecting the cathode layer from atmospheric oxidation, or a relatively thin layer of substantially transparent ITO. The first electrode can have a thickness of about 500 Angstroms to 4000 Angstroms. The first layer can have a thickness of about 50 Angstroms to about 5 micrometers, such as a thickness in the range of 100 Angstroms to 100 nm, 100 nm to 1 micrometer, or 1 micrometer to 5 micrometers. The second layer can have a thickness of about 50 Angstroms to about 5 micrometers, such as a thickness in the range of 100 Angstroms to 100 nm, 100 nm to 1 micrometer, or 1 micrometer to 5 micrometers. The second electrode can have a thickness of about 50 Angstroms to greater than about 1000 Angstroms.

A hole transporting layer (HTL) or an electron transporting layer (ETL) can include an inorganic material, such as an inorganic semiconductor. The inorganic semiconductor can be any material with a band gap greater than the emission energy of the emissive material. The inorganic semiconductor can include a metal chalcogenide, metal pnictide, or elemental semiconductor, such as a metal oxide, a metal sulfide, a metal selenide, a metal telluride, a metal nitride, a metal phosphide, a metal arsenide, or metal arsenide. For example, the inorganic material can include zinc oxide, a titanium oxide, a niobium oxide, an indium tin oxide, copper oxide, nickel oxide, vanadium oxide, chromium oxide, indium oxide, tin oxide, gallium oxide, manganese oxide, iron oxide, cobalt oxide, aluminum oxide, thallium oxide, silicon oxide, germanium oxide, lead oxide, zirconium oxide, molybdenum oxide, hafnium oxide, tantalum oxide, tungsten oxide, cadmium oxide, iridium oxide, rhodium oxide, ruthenium oxide, osmium oxide, a zinc sulfide, zinc selenide, zinc telluride, cadmium sulfide, cadmium selenide, cadmium telluride, mercury sulfide, mercury selenide, mercury telluride, silicon carbide, diamond (carbon), silicon, germanium, aluminum nitride, aluminum phosphide, aluminum arsenide, aluminum antimonide, gallium nitride, gallium phosphide, gallium arsenide, gallium antimonide, indium nitride, indium phosphide, indium arsenide, indium antimonide, thallium nitride, thallium phosphide, thallium arsenide, thallium antimonide, lead sulfide, lead selenide, lead telluride, iron sulfide, indium selenide, indium sulfide, indium telluride, gallium sulfide, gallium selenide, gallium telluride, tin selenide, tin telluride, tin sulfide, magnesium sulfide, magnesium selenide, magnesium telluride, or a mixture thereof. The metal oxide can be a mixed metal oxide, such as, for example, ITO. In a device, a layer of pure metal oxide (i.e., a metal oxide with a single substantially pure metal) can develop crystalline regions over time degrading the performance of the device. A mixed metal oxide can be less prone to forming such crystalline regions, providing longer device lifetimes than available with pure metal oxides. The metal oxide can be a doped metal oxide, where the doping is, for example, an oxygen deficiency, a halogen dopant, or a mixed metal. The inorganic semiconductor can include a dopant. In general, the dopant can be a p-type or an n-type dopant. An HTL can include a p-type dopant, whereas an ETL can include an n-type dopant.

Single crystalline inorganic semiconductors have been proposed for charge transport to semiconductor nanocrystals in devices. Single crystalline inorganic semiconductors are deposited by techniques that require heating the substrate to be coated to a high temperature. However, the top layer semiconductors must be deposited directly onto the nanocrystal layer, which is not robust to high temperature processes, nor suitable for facile epitaxial growth. Epitaxial techniques (such as chemical vapor deposition) can also be costly to manufacture, and generally cannot be used to cover a large area, (i.e., larger than a 12 inch diameter wafer). Advantageously, the inorganic semiconductor can be deposited on a substrate at a low temperature, for example, by sputtering. Sputtering is performed by applying a high voltage across a low-pressure gas (for example, argon) to create a plasma of electrons and gas ions in a high-energy state. Energized plasma ions strike a target of the desired coating material, causing atoms from that target to be ejected with enough energy to travel to, and bond with, the substrate. The substrate or the device being manufactured is cooled or heated for temperature control during the growth process. The temperature affects the crystallinity of the deposited material as well as how it interacts with the surface it is being deposited upon. The deposited material can be polycrystalline or amorphous. The deposited material can have crystalline domains with a size in the range of 10 Angstroms to 1 micrometer. Doping concentration can be controlled by varying the gas, or mixture of gases, which is used for the sputtering plasma. The nature and extent of doping can influence the conductivity of the deposited film, as well as its ability to optically quench neighboring excitons. By growing one material on top of another, p-n or p-i-n diodes can be created. The device can be optimized for delivery of charge to a semiconductor nanocrystal monolayer.

The layers can be deposited on a surface of one of the electrodes by spin coating, dip coating, vapor deposition, sputtering, or other thin film deposition methods. The second electrode can be sandwiched, sputtered, or evaporated onto the exposed surface of the solid layer. One or both of the electrodes can be patterned. The electrodes of the device can be connected to a voltage source by electrically conductive pathways. Upon application of the voltage, light is generated from the device.

Microcontact printing provides a method for applying a material to a predefined region on a substrate. The predefined region is a region on the substrate where the material is selectively applied. The material and substrate can be chosen such that the material remains substantially entirely within the predetermined area. By selecting a predefined region that forms a pattern, material can be applied to the substrate such that the material forms a pattern. The pattern can be a regular pattern (such as an array, or a series of lines), or an irregular pattern. Once a pattern of material is formed on the substrate, the substrate can have a region including the material (the predefined region) and a region substantially free of material. In some circumstances, the material forms a monolayer on the substrate. The predefined region can be a discontinuous region. In other words, when the material is applied to the predefined region of the substrate, locations including the material can be separated by other locations that are substantially free of the material.

In general, microcontact printing begins by forming a patterned mold. The mold has a surface with a pattern of elevations and depressions. A stamp is formed with a complementary pattern of elevations and depressions, for example by coating the patterned surface of the mold with a liquid polymer precursor that is cured while in contact with the patterned mold surface. The stamp can then be inked; that is, the stamp is contacted with a material which is to be deposited on a substrate. The material becomes reversibly adhered to the stamp. The inked stamp is then contacted with the substrate. The elevated regions of the stamp can contact the substrate while the depressed regions of the stamp can be separated from the substrate. Where the inked stamp contacts the substrate, the ink material (or at least a portion thereof) is transferred from the stamp to the substrate. In this way, the pattern of elevations and depressions is transferred from the stamp to the substrate as regions including the material and free of the material on the substrate. Microcontact printing and related techniques are described in, for example, U.S. Pat. Nos. 5,512,131; 6,180,239; and 6,518,168, each of which is incorporated by reference in its entirety. In some circumstances, the stamp can be a featureless stamp having a pattern of ink, where the pattern is formed when the ink is applied to the stamp. See U.S. patent application Ser. No. 11/253,612, filed Oct. 21, 2005, which is incorporated by reference in its entirety. Additionally, the ink can be treated (e.g., chemically or thermally) prior to transferring the ink from the stamp to the substrate. In this way, the patterned ink can be exposed to conditions that are incompatible with the substrate.

Quantum dot, with its broad absorption, narrow emission, high quantum yield and exceptional photostability, has drawn a lot of interest for its promising applications in biological imaging researches. Compared to conventional organic fluorophores, nanocrystals have shown advantages in multiple biological applications such as particle tracking and multiplexed imaging. Here, a color series of visible light emitting nanocrystals are developed with nearly unity photoluminescence (PL) quantum yield, symmetric and narrow emission spectral lineshapes (FWHM 20-25 nm) for highly multiplexed imaging. Additionally, InAs/CdSe/ZnS core/shell nanocrystals emitting in the short wavelength infrared (SWIR) region were also synthesized to widen the imaging range. To functionalize these nanocrystals for biological use, a norbornene-bearing organic ligand is developed. The ligand binds strongly to the surface of colloidal nanocrystallites during nanocrystal synthesis, which enables efficient conjugation of hydrophilic ligands via bioorthogonal click reaction between norbornene and tetrazine. An organic ligand that exhibits a norbornene functional group and binds strongly to the surface of colloidal nanocrystallites can be used during particle synthesis, eliminating the need for ligand exchange and enabling large-scale production of high quality hybrid nanomaterials. The molecule is compatible with state-of-the-art synthesis methods of a large variety of semiconductor nanocrystallites and metal oxide nanoparticles, making this a general method for making derivatizable nanomaterials.

In certain circumstances, the nanoparticles can be a perovskite, for example, a CsPbBr₃, or a CsPbI₃ material. Perovskite materials have a relatively high solubility product constant and are therefore unstable, to put a handle on the surface is very difficult without using the ligands and methods described herein.

A semiconductor nanocrystal composition can include a semiconductor nanocrystal, and an outer layer including a ligand bound to the nanocyrstal, wherein the ligand includes a norbornene group and a carboxyl group. The ligand includes a 5-norbornene-2-nonanoate.

The semiconductor nanocrystal can include a core of a first semiconductor material. The first semiconductor material is a Group II-VI compound, a Group II-V compound, a Group III-VI compound, a Group III-V compound, a Group IV-VI compound, a Group compound, a Group II-IV-VI compound, or a Group II-IV-V compound. The first semiconductor material is ZnS, ZnSe, ZnTe, CdS, CdSe, CdTe, HgS, HgSe, HgTe, A1N, AlP, AlAs, AlSb, GaN, GaP, GaAs, GaSb, GaSe, InN, InP, InAs, InSb, TlN, TlP, TlAs, TlSb, PbS, PbSe, PbTe, or mixtures thereof.

The semiconductor nanocrystal includes a second semiconductor material overcoated on the first semiconductor material. The first semiconductor material has a first band gap, and the second semiconductor material has a second band gap that is larger than the first band gap. The second semiconductor material is a Group II-VI compound, a Group II-V compound, a Group III-VI compound, a Group III-V compound, a Group IV-VI compound, a Group compound, a Group II-IV-VI compound, or a Group II-IV-V compound. The second semiconductor material is ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TlN, TlP, TlAs, TlSb, TlSb, PbS, PbSe, PbTe, or mixtures thereof.

Semiconductor nanocrystals demonstrate quantum confinement effects in their luminescence properties. When semiconductor nanocrystals are illuminated with a primary energy source, a secondary emission of energy occurs at a frequency related to the band gap of the semiconductor material used in the nanocrystal. In quantum confined particles, the frequency is also related to the size of the nanocrystal.

The semiconductor forming the nanocrystals can include a Group II-VI compound, a Group II-V compound, a Group III-VI compound, a Group III-V compound, a Group IV-VI compound, a Group compound, a Group II-IV-VI compound, or a Group II-IV-V compound, for example, ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TlN, TlP, TlAs, TlSb, TlSb, PbS, Pb Se, PbTe, Cd₃As₂, Cd₃P₂ or mixtures thereof.

The nanocrystal can be a member of a population of nanocrystals having a narrow size distribution. The nanocrystal can be a sphere, rod, disk, or other shape. The nanocrystal can include a core of a semiconductor material. The nanocrystal can include a core having the formula MX (e.g., for a II-VI semiconductor material) or M₃X₂ (e.g., for a II-V semiconductor material), where M is cadmium, zinc, magnesium, mercury, aluminum, gallium, indium, thallium, or mixtures thereof, and X is oxygen, sulfur, selenium, tellurium, nitrogen, phosphorus, arsenic, antimony, or mixtures thereof.

The emission from the nanocrystal can be a narrow Gaussian emission band that can be tuned through the complete wavelength range of the ultraviolet, visible, or infrared regions of the spectrum by varying the size of the nanocrystal, the composition of the nanocrystal, or both. For example, both CdSe and CdS can be tuned in the visible region and InAs can be tuned in the infrared region. Cd₃As₂ can be tuned from the visible through the infrared.

A population of nanocrystals can have a narrow size distribution. The population can be monodisperse and can exhibit less than a 15% rms deviation in diameter of the nanocrystals, preferably less than 10%, more preferably less than 5%. Spectral emissions in a narrow range of between 10 and 100 nm full width at half max (FWHM) can be observed. Semiconductor nanocrystals can have emission quantum efficiencies (i.e., quantum yields, QY) of greater than 2%, 5%, 10%, 20%, 40%, 60%, 70%, 80%, or 90%. In some cases, semiconductor nanocrystals can have a QY of at least 90%, at least 91%, at least 92%, at least 93%, at least 94%, at least 95%, at least 96%, at least 97%, at least 97%, at least 98%, or at least 99%.

Size distribution during the growth stage of the reaction can be estimated by monitoring the absorption line widths of the particles. Modification of the reaction temperature in response to changes in the absorption spectrum of the particles allows the maintenance of a sharp particle size distribution during growth. Reactants can be added to the nucleation solution during crystal growth to grow larger crystals. By stopping growth at a particular nanocrystal average diameter and choosing the proper composition of the semiconducting material, the emission spectra of the nanocrystals can be tuned continuously over the wavelength range of 300 nm to 5 microns, or from 400 nm to 800 nm for CdSe and CdTe. The nanocrystal has a diameter of less than 150 Å. A population of nanocrystals has average diameters in the range of 15 Å to 125 Å.

The core can have an overcoating on a surface of the core. The overcoating can be a semiconductor material having a composition different from the composition of the core. The overcoat of a semiconductor material on a surface of the nanocrystal can include a Group II-VI compound, a Group II-V compound, a Group III-VI compound, a Group III-V compound, a Group IV-VI compound, a Group compound, a Group II-IV-VI compound, and a Group II-IV-V compound, for example, ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TlN, TlP, TlAs, TlSb, TlSb, PbS, Pb Se, PbTe, Cd₃As₂, Cd₃P₂ or mixtures thereof. For example, ZnS, ZnSe or CdS overcoatings can be grown on CdSe or CdTe nanocrystals. An overcoating process is described, for example, in U.S. Pat. No. 6,322,901. By adjusting the temperature of the reaction mixture during overcoating and monitoring the absorption spectrum of the core, over coated materials having high emission quantum efficiencies and narrow size distributions can be obtained. The overcoating can be between 1 and 10 monolayers thick.

Shells are formed on nanocrystals by introducing shell precursors at a temperature where material adds to the surface of existing nanocrystals but at which nucleation of new particles is rejected. In order to help suppress nucleation and anisotropic elaboration of the nanocrystals, selective ionic layer adhesion and reaction (SILAR) growth techniques can be applied. See, e.g., U.S. Pat. No. 7,767,260, which is incorporated by reference in its entirety. In the SILAR approach, metal and chalcogenide precursors are added separately, in an alternating fashion, in doses calculated to saturate the available binding sites on the nanocrystal surfaces, thus adding one-half monolayer with each dose. The goals of such an approach are to: (1) saturate available surface binding sites in each half-cycle in order to enforce isotropic shell growth; and (2) avoid the simultaneous presence of both precursors in solution so as to minimize the rate of homogenous nucleation of new nanoparticles of the shell material.

In the SILAR approach, it can be beneficial to select reagents that react cleanly and to completion at each step. In other words, the reagents selected should produce few or no reaction by-products, and substantially all of the reagent added should react to add shell material to the nanocrystals. Completion of the reaction can be favored by adding sub-stoichiometric amounts of the reagent. In other words, when less than one equivalent of the reagent is added, the likelihood of any unreacted starting material remaining is decreased.

The quality of core-shell nanocrystals produced (e.g., in terms of size monodispersity and QY) can be enhanced by using a constant and lower shell growth temperature. Alternatively, high temperatures may also be used. In addition, a low-temperature or room temperature “hold” step can be used during the synthesis or purification of core materials prior to shell growth.

The outer surface of the nanocrystal can include a layer of compounds derived from the coordinating agent used during the growth process. The surface can be modified by repeated exposure to an excess of a competing coordinating group to form an overlayer. For example, a dispersion of the capped nanocrystal can be treated with a coordinating organic compound, such as pyridine, to produce crystals which disperse readily in pyridine, methanol, and aromatics but no longer disperse in aliphatic solvents. Such a surface exchange process can be carried out with any compound capable of coordinating to or bonding with the outer surface of the nanocrystal, including, for example, phosphines, thiols, amines and phosphates. The nanocrystal can be exposed to short chain polymers which exhibit an affinity for the surface and which terminate in a moiety having an affinity for a suspension or dispersion medium. Such affinity improves the stability of the suspension and discourages flocculation of the nanocrystal. Nanocrystal coordinating compounds are described, for example, in U.S. Pat. No. 6,251,303, which is incorporated by reference in its entirety.

A perovskite material can have the formula (I):

APbX₃ (I)

where A is an organic or molecular cation (such as ammonium, methylammonium, formamidimium, phosphonium, cesium, etc.), and X is a halide ion (such as I, Br, or Cl).

Alternatively, a perovskite material can have the formula (II):

AₓA′₁₋ₓB_{y}B′_{1-y}O_{3±δ} (II)

where each of A and A′, independently, is a rare earth, alkaline earth metal, or alkali metal, x is in the range of 0 to 1, each of B and B′, independently, is a transition metal, y is in the range of 0 to 1, and δ is in the range of 0 to 1. δ can represent the average number of oxygen-site vacancies (i.e., −δ) or surpluses (i.e., +δ); in some cases, δ is in the range of 0 to 0.5, 0 to 0.25, 0 to 0.15, 0 to 0.1, or 0 to 0.05. For clarity, it is noted that in formula (I), B and B′ do not represent the element boron, but instead are symbols that each independently represent a transition metal. In some cases, δ can be approximately zero, i.e., the number of oxygen-site vacancies or surpluses is effectively zero. The material can in some cases have the formula AB_{y}B′_{1-y}O₃ (i.e., when x is 1 and δ is 0); AₓA′₁₋ₓBO₃ (i.e., when y is 1 and δ is 0); or ABO₃ (i.e., when x is 1, y is 1 and δ is 0).

Rare earth metals include Sc, Y, La, Ce, Pr, Nd, Pm, Sm, Eu, Gd, Tb, Dy, Ho, Er, Tm, Yb, or Lu. Alkaline earth metals include Be, Mg, Ca, Sr, Ba, and Ra. Alkali metals include Li, Na, K, Rb, and Cs. Transition metals include Sc, Ti, V, Cr, Mn, Fe, Co, Ni, Cu, Zn, Y, Zr, Nb, Mo, Tc, Ru, Rh, Pd, Ag, Cd, Hf, Ta, W, Re, Os, Ir, Pt, Au, or Hg. Particularly useful alkaline earth metals can include Ca, Sr, and Ba. Particularly useful transition metals can include first-row transition metals, for example, Cr, Mn, Fe, Co, Ni, and Cu. Representative materials of formula (I) include calcium titanate (CaTiO₃), barium titanate (BaTiO₃), strontium titanate (SrTiO₃), barium ferrite (BaFeO₃), KTaO₃, NaNbO₃, PbTiO₃, LaMnO₃,SrZrO₃, SrHfO₃,SrSnO₃, SrFeO₃, BaZrO₃, BaHfO₃, KNbO₃, BaSnO₃, EuTiO₃, RbTaO₃, GdFeO₃, PbHfO₃, LaCrO₃, PbZrO₃, or LiNbO₃.

Disclosed herein is an inverted planar perovskite solar cell utilizing a plurality of semiconductor nanocrystals as hole transport materials (HTMs). In certain embodiments, the semiconductor nanocrystals can have a core/shell structure. In certain embodiments, a plurality of semiconductor nanocrystals can include lead sulfide (PbS) and lead sulfide/cadmium sulfide (PbS/CdS) core/shell quantum dots (nanocrystals). In certain embodiments, lead halide perovskite can be incorporated as a main absorber material and core/shell nanocrystals as the HTM in an inverted architecture of photovoltaic devices. In certain embodiments, MAPbI₃ can be used as the main absorber material and PbS/CdS core/shell nanocrystals can function as the HTM.

In addition to being able to solution process nanocrystals at low temperatures, PbS nanocrystals are a promising material for this application due to the ability to systematically modify nanocrystal energy levels. This can be accomplished synthetically by varying nanocrystal size, and also through post-synthesis processing, such as shell growth and ligand exchange. This is a unique advantage, allowing for fine-tuning and control over energy level alignments (see Brown, P. R.; Kim, D.; Lunt, R. R.; Zhao, N.; Bawendi, M. G.; Grossman, J. C.; Bulović, V. ACS Nano 2014, 8 (6), 5863-5872, and Chuang, C.-H. M.; Brown, P. R.; Bulović, V; Bawendi, M. G. Nat. Mater. 2014, 13 (8), 796-801, each of which is incorporated by reference in its entirety), as well as the surface chemistry at interfaces.

The application of a PbS nanocrystal HTM in the inverted device is the only example that does not use high temperature processed TiO₂. See, Hu, L.; Wang, W.; Liu, H.; Peng, J.; Cao, H.; Shao, G.; Xia, Z.; Ma, W.; Tang, J. J. Mater. Chem. A 2015, 3 (2), 515-518, which is incorporated by reference in its entirety. Efficiencies for the existing examples above range between 3-8%. The structure disclosed herein shows a significant improvement on the use of PbS nanocrystals in perovskite solar cells.

This work reports the use of ex-situ synthesized PbS core and PbS/CdS core/shell colloidal nanocrystals as the HTM in planar perovskite solar cells. It is of particular note that, with the exception of electrode deposition, the device fabrication steps all employ low temperature (≤70° C.), solution processing methodologies. FIGS. 1A and 1B show a cross-sectional scanning electron micrograph (SEM) and a schematic, respectively, of the device architecture. Specifically, indium-doped tin oxide (ITO) patterned on glass functions as the bottom electrode and the hole transport layer consists of either PbS nanocrystals or PbS/CdS core/shell nanocrystals. Purified nanocrystals are deposited via layer-by-layer spin coating from octane in ambient air lab conditions (room temperature and less than 40% relative humidity). Each nanocrystal layer is subjected to a 30 second solid-state ligand exchange with a solution of 1,2-ethanedithiol (1,2-EDT) in acetonitrile. These ligand-exchanged films are exposed to ambient air at room temperature for up to two hours before transferring to a nitrogen-filled glovebox for further processing. The MAPbI₃ absorber layer is deposited onto the nanocrystal film through sequential deposition of precursor materials. See, Liu, D.; Kelly, T. L. Nat. Photonics 2013, 8 (2), 133-138, Burschka, J.; Pellet, N.; Moon, S.-J.; Humphry-Baker, R.; Gao, P.; Nazeeruddin, M. K.; Grätzel, M. Nature 2013, 499 (7458), 316-319, Wu, Y.; Islam, A.; Yang, X.; Qin, C.; Liu, J.; Zhang, K.; Peng, W.; Han, L. Energy Environ. Sci. 2014, 7 (9), 2934, and Im, J.-H.; Jang, I.-H.; Pellet, N.; Grätzel, M.; Park, N.-G. Nat. Nanotechnol. 2014, 9 (11), 927-932, each of which is incorporated by reference in its entirety. Lead iodide (PbI₂) is dissolved in N,N-dimethylformamide by stirring at 70° C. and films are spin cast from the solution held at this temperature. The PbI₂ film is set aside for approximately 15-30 minutes to dry at room temperature until it has a yellow, opaque appearance. The dried PbI₂ film is then coated with methylammonium iodide (MAI) dissolved in isopropanol for 30 seconds. Upon treatment with MAI, the film transitions from yellow to dark brown within seconds and do not require any thermal annealing before proceeding to the next steps. The MAPbI₃ film morphology (top-view) shown in FIG. 1C is consistent with the cuboid structures formed in previous reports of perovskite solar cells that employ the sequential deposition method. See, Liu, D.; Kelly, T. L. Nat. Photonics 2013, 8 (2), 133-138, Wu, Y.; Islam, A.; Yang, X.; Qin, C.; Liu, J.; Zhang, K.; Peng, W.; Han, L. Energy Environ. Sci. 2014, 7 (9), 2934, and Im, J.-H.; Jang, I.-H.; Pellet, N.; Grätzel, M.; Park, N.-G. Nat. Nanotechnol. 2014, 9 (11), 927-932, each of which is incorporated by reference in its entirety. The electron transport layer consists of a [6,6]-phenyl-C₆₁-butyric acid methyl ester (PCBM) film spin cast from chloroform and the device is completed with a thermally evaporated aluminum top electrode.

To-date, certified research-cell efficiencies for nanocrystal-only solar cells have reached approximately 10%. Improved surface passivation and the capability to modify nanocrystal energy levels through ligand exchange have contributed to this progress. See, Brown, P. R.; Kim, D.; Lunt, R. R.; Zhao, N.; Bawendi, M. G.; Grossman, J. C.; Bulović, V. ACS Nano 2014, 8 (6), 5863-5872, Chuang, C.-H. M.; Brown, P. R.; Bulović, V.; Bawendi, M. G. Nat. Mater. 2014, 13 (8), 796-801, Tang, J.; Kemp, K. W.; Hoogland, S.; Jeong, K. S.; Liu, H.; Levina, L.; Furukawa, M.; Wang, X.; Debnath, R.; Cha, D.; Chou, K. W.; Fischer, A.; Amassian, A.; Asbury, J. B.; Sargent, E. H. Nat. Mater. 2011, 10 (10), 765-771, Ip, A. H.; Thon, S. M.; Hoogland, S.; Voznyy, O.; Zhitomirsky, D.; Debnath, R.; Levina, L.; Rollny, L. R.; Carey, G. H.; Fischer, A.; Kemp, K. W.; Kramer, I. J.; Ning, Z.; Labelle, A. J.; Chou, K. W.; Amassian, A.; Sargent, E. H. Nat. Nanotechnol. 2012, 7 (9), 577-582, Yuan, M.; Zhitomirsky, D.; Adinolfi, V; Voznyy, O.; Kemp, K. W.; Ning, Z.; Lan, X.; Xu, J.; Kim, J. Y.; Dong, H.; Sargent, E. H. Adv. Mater. 2013, 25 (39), 5586-5592, Jasieniak, J.; Califano, M.; Watkins, S. E. ACS Nano 2011, 5 (7), 5888-5902, Soreni-Harari, M.; Yaacobi-Gross, N.; Steiner, D.; Aharoni, A.; Banin, U.; Millo, O.; Tessler, N. Nano Lett. 2008, 8 (2), 678-684, and Greaney, M. J.; Das, S.; Webber, D. H.; Bradforth, S. E.; Brutchey, R. L. ACS Nano 2012, 6 (5), 4222-4230, each of which is incorporated by reference in its entirety. The active layer absorbance of these high efficiency PbS nanocrystal solar cells extends into the near-infrared region in order to increase the photogenerated current.

This work here discloses an example of an inverted solar cell structure with MAPbI₃ as the main absorber material and nanocrystals with PbS core as the HTM. Other nanocrystal materials, such as CdS and CdSe, can be used as electron selective materials. See, Juarez-Perez, E. J.; Wuβler, M.; Fabregat-Santiago, F.; Lakus-Wollny, K.; Mankel, E.; Mayer, T.; Jaegermann, W.; Mora-Sero, I. J. Phys. Chem. Lett. 2014, 5 (4), 680-685, Gu, Z.; Chen, F.; Zhang, X.; Liu, Y.; Fan, C.; Wu, G.; Li, H.; Chen, H. Sol. Energy Mater. Sol. Cells 2015, 140, 396-404, and Wang, L.; Fu, W.; Gu, Z.; Fan, C.; Yang, X.; Li, H.; Chen, H. J. Mater. Chem. C 2014, 2 (43), 9087-9090, each of which is incorporated by reference in its entirety. In contrast, PbS nanocrystals have been shown to exhibit ambipolar behavior. See, Osedach, T. P.; Zhao, N.; Andrew, T. L.; Brown, P. R.; Wanger, D. D.; Strasfeld, D. B.; Chang, L.-Y.; Bawendi, M. G.; Bulović, V. ACS Nano 2012, 6 (4), 3121-3127, Balazs, D. M.; Nugraha, M. I.; Bisri, S. Z.; Sytnyk, M.; Heiss, W.; Loi, M. a. Appl. Phys. Lett. 2014, 104 (11), 112104, Balazs, D. M.; Nugraha, M. I.; Bisri, S. Z.; Sytnyk, M.; Heiss, W.; Loi, M. a. Appl. Phys. Lett. 2014, 104 (11), 112104, Zarghami, M. H.; Liu, Y; Gibbs, M.; Gebremichael, E.; Webster, C.; Law, M. ACS Nano 2010, 4 (4), 2475-2485, Schornbaum, J.; Zakharko, Y.; Held, M.; Thiemann, S.; Gannott, F.; Zaumseil, J. Nano Lett. 2015, 15 (3), 1822-1828, and Koh, W.; Saudari, S. R.; Fafarman, A. T.; Kagan, C. R.; Murray, C. B. Nano Lett. 2011, 11 (11), 4764-4767, each of which is incorporated by reference in its entirety.

If the potential absorption losses that occur in window layers are considered (see Hegedus, S. S.; Shafarman, W. N. Prog. Photovoltaics Res. Appl. 2004, 12 (23), 155-176, Wu, X. Sol. Energy 2004, 77 (6), 803-814, Desalvo, G. C.; Bamett, A. M.; Member, S. IEEE Trans. Electron Devices 1993, 40 (4), 705-711, Yan, B.; Zhao, L.; Zhao, B.; Chen, J.; Diao, H.; Wang, G.; Mao, Y; Wang, W. J. Non. Cryst. Solids 2012, 358 (23), 3243-3247, and Irwin, M. D.; Buchholz, D. B.; Hains, A. W.; Chang, R. P. H.; Marks, T. J. Proc. Natl. Acad. Sci. 2008, 105 (8), 2783-2787, each of which is incorporated by reference in its entirety) in the context of the inverted device configuration used in this work, there can be limited benefit to using PbS nanocrystals with an absorbance profile that extends into the near-infrared region. The size-dependent bandgap tunability of colloidal nanocrystals can be a solution to this potential problem. In certain embodiments, nanocrystals can be synthesized to produce a wider bandgap. For example, the first excitonic absorbance feature of the smallest PbS nanocrystals has an optical bandgap at 1.96 eV (633 nm) in solution. The bandgap energy increases as the PbS nanocrystal size is reduced, and therefore it is expected to observe an increase in the open circuit voltage (V_{OC}) of the solar cell because the decreasing conduction band energy favors electron blocking behavior and the energy of the PbS nanocrystal valence band increases which lowers the barrier for hole extraction. See, Hu, L.; Wang, W.; Liu, H.; Peng, J.; Cao, H.; Shao, G.; Xia, Z.; Ma, W.; Tang, J. J. Mater. Chem. A 2015, 3 (2), 515-518, and Hyun, B.-R.; Zhong, Y.-W.; Bartnik, A. C.; Sun, L.; Abruña, H. D.; Wise, F. W.; Goodreau, J. D.; Matthews, J. R.; Leslie, T. M.; Borrelli, N. F. ACS Nano 2008, 2 (11), 2206-2212, each of which is incorporated by reference in its entirety. In order to study how nanocrystal size affects the V_{OC} in the device architecture, a size series of PbS nanocrystals was synthesized according to a scaled-up literature protocol. For the protocol, see Liu, T.-Y.; Li, M.; Ouyang, J.; Zaman, M. B.; Wang, R.; Wu, X.; Yeh, C.-S.; Lin, Q.; Yang, B.; Yu, K. J. Phys. Chem. C 2009, 113 (6), 2301-2308, which is incorporated by reference in its entirety. The nanocrystal size was tuned by holding the molar ratios of lead-precursor, sulfur-precursor, and oleic acid constant and then varying the injection temperature from 30° C. to 120° C. (Table 1). See, Liu, T.-Y; Li, M.; Ouyang, J.; Zaman, M. B.; Wang, R.; Wu, X.; Yeh, C.-S.; Lin, Q.; Yang, B.; Yu, K. J. Phys. Chem. C 2009, 113 (6), 2301-2308, and Hines, M. A.; Scholes, G. D. Adv. Mater. 2003, 15 (21), 1844-1849, each of which is incorporated by reference in its entirety.

TABLE 1
Growth parameters for PbS core-only nanocrystal size series

| | First | | | |
|---|---|---|---|---|
| | excitonic | | | |
| | absorbance | Pb- | S- | |
| | feature | precursor | precursor | Growth parameters |
| PbS rxn 1 | 633 nm | 10 mL | 5 mL | Injection at 30° C., followed by |
| | | | | heating at a rate of 2° C./min to a |
| | | | | set-point temperature of 50° C., |
| | | | | growth time of 5 minutes at 50° C. |
| PbS rxn 2 | 652 nm | 10 mL | 5 mL | Injection at 50° C., growth time of |
| | | | | 10 minutes. |
| PbS rxn 3 | 719 nm | 10 mL | 5 mL | Injection at 85° C., growth time of |
| | | | | 5 minutes. |
| PbS rxn 4 | 794 nm | 9 mL | 4.5 mL | Injection at 120° C., growth time |
| | | | | of 3 minutes. |

### EXAMPLES

### Materials

Lead (II) oxide (PbO, Aldrich, 99.999%), hexamethyldisilathiane ((TMS)₂S, Aldrich, synthesis grade), oleic acid (OA, TCI, >85.0%), 1-octadecene (ODE, Aldrich, technical grade, 90%), cadmium oxide (CdO, Aldrich, ≥99.99% trace metals basis), methylamine (Aldrich, 33 wt % in absolute ethanol), hydriodic acid (HI, Sigma-Aldrich, 57 wt% in water, distilled, stabilized, 99.95%), lead (II) iodide (PbI₂, Aldrich, 99%) 1,2-ethanedithiol (1,2-EDT, Fluka, purum >98.0%), octane (anhydrous, Sigma-Aldrich, ≥99%), acetonitrile (anhydrous, Sigma-Aldrich, 99.8%), N,N-dimethylformamide (anhydrous, Sigma-Aldrich, 99.8%), isopropanol (anhydrous, Sigma-Aldrich, 99.5%), chloroform (anhydrous, Sigma-Aldrich, stabilized with amylenes, ≥99.5%), indium-doped tin oxide (ITO, Thin Film Devices), [6,6]-phenyl-C61-butyric acid methyl ester (PCBM, Aldrich, >99%), aluminum (99.999%).

### Synthesis of PbS Core Nanocrystal Size Series

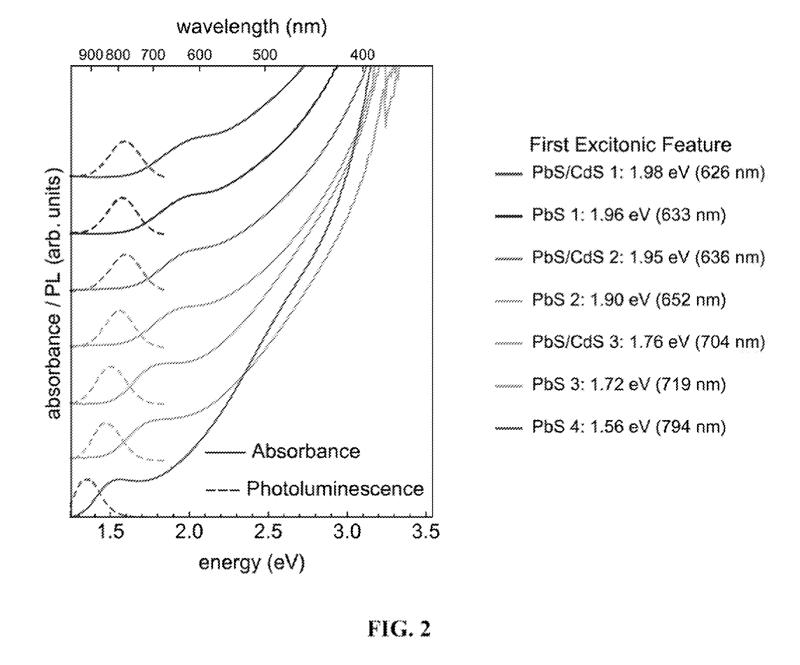

PbS cores were prepared by following a scaled-up literature protocol by Liu et al. Liu, T.-Y.; Li, M.; Ouyang, J.; Zaman, M. B.; Wang, R.; Wu, X.; Yeh, C.-S.; Lin, Q.; Yang, B.; Yu, K. J. Phys. Chem. C 2009, 113 (6), 2301-2308, which is incorporated by reference in its entirety. Synthesis was performed under inert nitrogen on the Schlenk line. To prepare the Pb-precursor stock solution, PbO (0.900 g, 4.03 mmol) was added to a 100 mL three-neck flask containing OA (2.5 mL, 7.9 mmol) and ODE (37.5 mL). While stirring, the solution was degassed at room temperature until the pressure reached 100-150 mTorr. The line was then switched to nitrogen and the solution was heated to 120° C. using a heating mantle and temperature controller until the solution became clear and colorless. The solution was cooled to 100° C. and degassed until the pressure reached 100-150 mTorr. The Pb-precursor stock solution was further cooled to room temperature and set aside for later use. To prepare the S-precursor stock solution, ODE (20 mL) in a septum-capped vial was degassed for an hour while stirring at room temperature. The vial was transferred to a nitrogen-filled glovebox and (TMS)₂S (0.42 mL, 1.99 mmol) was added. The S-precursor stock solution was kept in the glovebox prior to use. These stock solutions were used to synthesize the core-only size series according to the parameters in Table 1. In each reaction, the molar ratio of Pb:S:OA was kept constant at approximately 2:1:4. The Pb-precursor was stirred at 650 rpm and degassed at room temperature. The reaction flask was then placed under nitrogen and equilibrated to the injection temperature using an oil bath (growth temperature monitored with oil bath temperature). The S-precursor was removed from the glovebox in a syringe and subsequently injected into the reaction flask. For the reactions involving S-precursor injection at 30° C. and 50° C., the observed color change was slower and transitioned from yellow to orange to red and lastly to a red-tinted brown. PbS nanocrystal crude solutions are transferred to a septum-capped vial and stored in the glovebox. The small PbS nanocrystals slowly ripen and grow over time when stored in the growth solution. PbS rxn 1 was performed on a different day than the rest of the size series. Absorbance and photoluminescence for the PbS core-only nanocrystal size series is shown in FIG. 2.

### Preparation of PbS/CdS Core/Shell Nanocrystal Size Series via Cation Exchange

PbS/CdS core/shell nanocrystals were prepared by following a modified literature protocol by Liu et al. See, Liu, T.-Y.; Li, M.; Ouyang, J.; Zaman, M. B.; Wang, R.; Wu, X.; Yeh, C.-S.; Lin, Q.; Yang, B.; Yu, K. J. Phys. Chem. C 2009, 113 (6), 2301-2308, which is incorporated by reference in its entirety. To prepare a stock solution of Cd-OA, CdO (0.218 g, 1.70 mmol) was added to a 50 mL three-neck flask containing OA (1.6 mL, 5.1 mmol) and ODE (12.7 mL). While stirring, the solution was degassed at room temperature until the pressure reached 100-150 mTorr. The reaction flask was then placed under nitrogen and heated to 200° C. using a heating mantle and temperature controller until the solution became clear and slightly yellow-brown tinted. The solution was cooled to 100° C. and degassed until the pressure reached 100-150 mTorr. The Cd-OA stock solution was cooled to room temperature and transferred to a septum-capped vial for storage. The same Cd-OA stock solution was used for all cation exchange treatments discussed in this work. For each of the PbS core sizes described in the previous section (PbS rxns 1-4), 2.5 mL of the growth solution was transferred to a 20 mL septum-capped vial and degassed at room temperature while stirring at 650 rpm. After degassing, the vial was placed under nitrogen and 0.15 mL of degassed Cd-OA solution was injected. The cation exchange treatment was stopped after 5 minutes with the addition of isopropanol to precipitate the core/shell nanocrystals. Precipitation was performed in air in a fume hood. The largest PbS cores did not undergo cation exchange (no blue shift in the first excitonic absorbance feature and nanocrystals became aggregated after purification). This is not entirely unexpected, however, because Cd²⁺ cation exchange with larger PbS nanocrystals is typically performed at elevated temperatures (i.e., 80-100° C.). Absorbance and photoluminescence for the PbS/CdS core/shell nanocrystal size series is shown in FIG. 2.

### Preparation of PbS/CdS Core/Shell Nanocrystals for Cd-OA Treatment Series

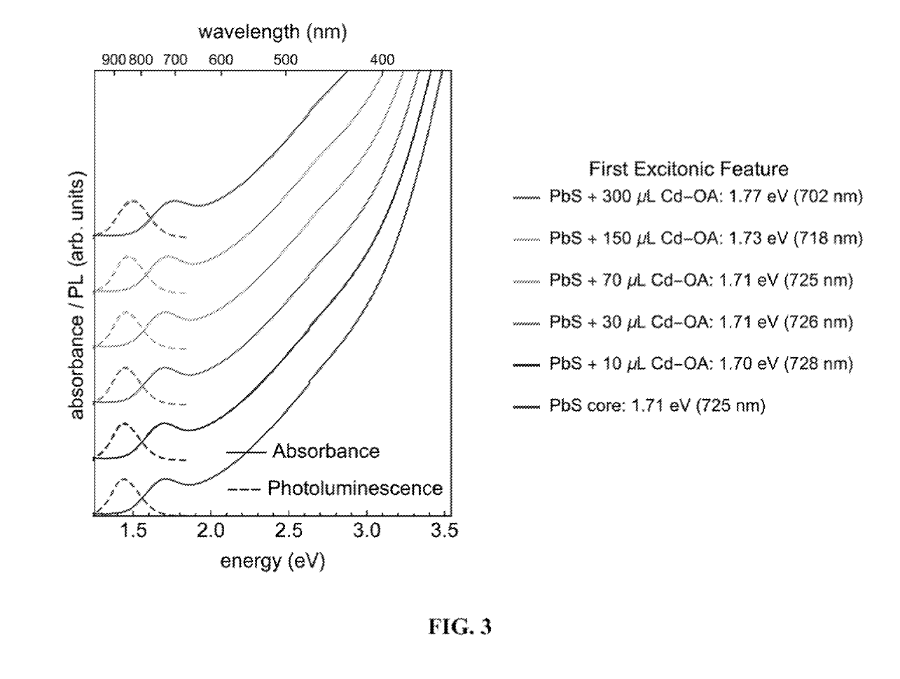

For the Cd-OA treatment series, PbS/CdS core/shell nanocrystals were prepared using the same process described in the previous section but by varying the amount of Cd-OA stock solution used in the treatment. PbS cores with a first excitonic absorbance feature at 725 nm were used for this series. 2.5 mL of growth solution was treated with the following volumes of Cd-OA stock solution: 10 μL, 30 μL, 70 μL, 150 μL, and 300 μL. The cation exchange treatment was stopped after 5 minutes with the addition of isopropanol to precipitate the core/shell nanocrystals. Precipitation was performed in air in a fume hood. Absorbance and photoluminescence for the Cd-OA treatment series is shown in FIG. 3.

### Synthesis of Methylammonium Iodide

Methylammonium iodide (MAI) was synthesized using a procedure similar to a previous report in the literature. See, Lee, M. M.; Teuscher, J.; Miyasaka, T.; Murakami, T. N.; Snaith, H. J. Science (80-.). 2012, 338 (6107), 643-647, which is incorporated by reference in its entirety. Absolute ethanol (200 mL) and HI (20 mL) were transferred to a 500 mL round bottom flask. Methylamine (50 mL) was added to the reaction flask via syringe and the reaction was stirred at room temperature for 2 hours. Solvent was evaporated using a rotary evaporator with the water bath heating at 50° C., yielding a white powder. MAI was further purified through recrystallization with ethanol and diethyl ether. The isolated white crystals were dried under high vacuum on the Schlenk line overnight then transferred to a nitrogen-filled glovebox for storage.

### Device Fabrication

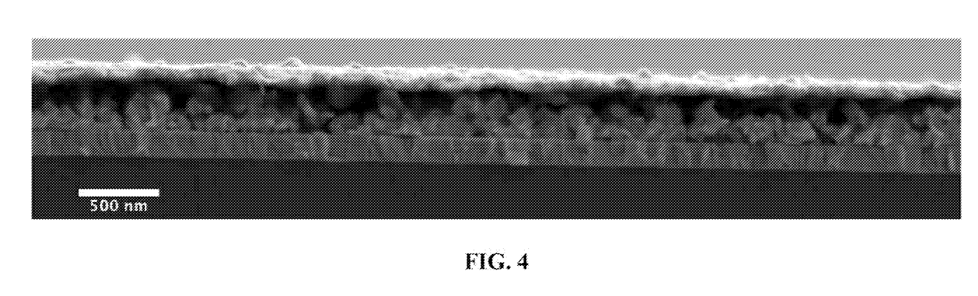

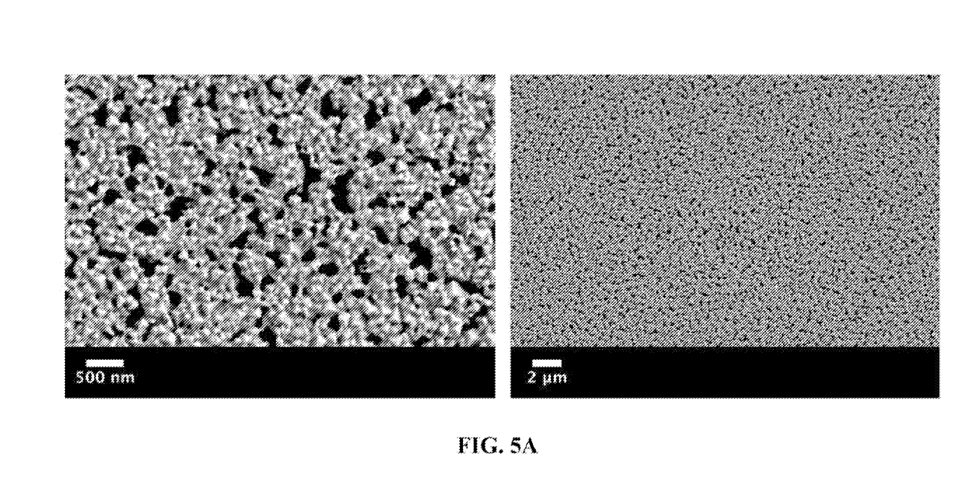

Cross-sectional scanning electron micrograph of a complete device is shown in FIG. 4.

### Substrate Preparation:

Pre-patterned ITO electrodes on glass were cleaned through sonication for 20 minutes each in detergent (2% Micro-90 in deionized water), deionized water, acetone, and isopropanol. Cleaned substrates were dried using a flow of nitrogen then oxygen plasma cleaned for 5-10 minutes.

### Nanocrystal Film Deposition:

Nanocrystals were purified in air in a fume hood. To purify nanocrystals, three cycles of precipitation with isopropanol (hard crash with almost colorless supernatant), centrifugation at 6000 rpm, and isolation of precipitate was performed. After the first two precipitations and isolations, the nanocrystals were re-dissolved in hexane. After the final precipitation, isolated nanocrystals were dried under a flow of dry nitrogen and dissolved in anhydrous octane to a concentration of 8 mg/mL. nanocrystal solutions were filtered through a 13 mm 0.45 μm PTFE syringe filter prior to use. Nanocrystal film deposition was done through layer-by-layer spin coating in a fume hood under ambient lab conditions (room temperature and less than 40% relative humidity). Higher levels of humidity affected film quality and caused some areas of the films to delaminate when humidity was above 50-60%. 15-20 μL of filtered nanocrystals were spun onto clean ITO/glass substrates for 20 seconds at 2500 rpm. Films were then coated with a solution of 1,2-EDT in anhydrous acetonitrile (2 vol % prepared in glovebox prior to use) for 30 seconds, rinsed with anhydrous acetonitrile three times, and spun dry. This process was performed a total of 3 times. The solid state ligand exchange insolubilizes the nanocrystals to the solvents used in the following fabrication steps. Films were exposed to ambient air for up to two airs and then transferred to a nitrogen-filled glovebox for storage overnight.

### MAPbI₃ Perovskite Film Deposition:

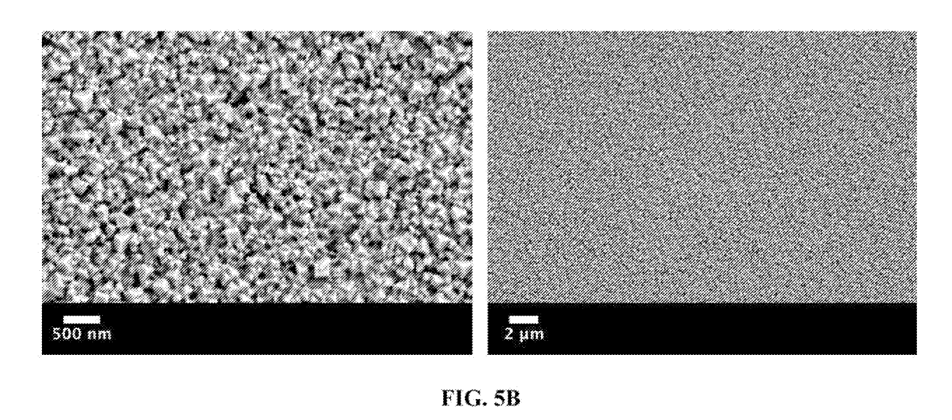

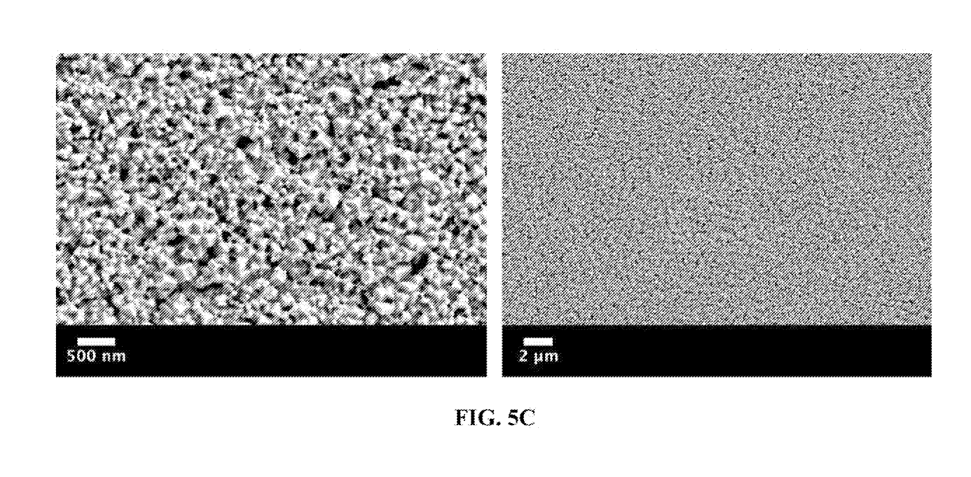

The sequential deposition process used to prepare MAPbI₃ films is similar to previous reports in the literature. See, Burschka, J.; Pellet, N.; Moon, S.-J.; Humphry-Baker, R.; Gao, P.; Nazeeruddin, M. K.; Grätzel, M. Nature 2013, 499 (7458), 316-319, Wu, Y.; Islam, A.; Yang, X.; Qin, C.; Liu, J.; Zhang, K.; Peng, W.; Han, L. Energy Environ. Sci. 2014, 7 (9), 2934 and Liu, D.; Kelly, T. L. Nat. Photonics 2013, 8 (2), 133-138, each of which is incorporated by referenc ein its entirety. Deposition is carried out in a nitrogen-filled glovebox. PbI₂ is weighed out and dissolved in anhydrous DMF to a concentration of 300 mg/mL. In order to completely dissolve PbI₂, the solution is stirred at 70° C. on a hotplate. MAI is weighed out and dissolved in anhydrous isopropanol to a concentration of 10 mg/mL (vortex mixing is utilized to aid in dissolution). 50 μL of PbI₂ (solution kept at 70° C. for spin coating) is deposited onto the nanocrystal films by spin coating for 45 seconds at 3000 rpm. The film is set aside in a fluoroware container until it dries to an opaque, yellow color (approximately 15-30 minutes). The dried PbI₂ film is then placed back onto the spin coater and coated with 150 μL of MAI solution. The film is treated for 30 seconds, rinsed with anhydrous isopropanol three times, and then spun dry. Isopropanol is an orthogonal solvent and does not dissolve the PbI₂ or MAPbI₃ films for the processing times used. Upon coating with MAI solution, the film transitions from yellow to dark brown within seconds. The perovskite films were not thermally annealed. Scanning electron micrographs of the MAPbI₃ films with and without nanocrystals are shown in FIG. 5.

### PCBM Film Deposition:

PCBM is weighed out and dissolved in anhydrous chloroform, an orthogonal solvent to the MAPbI₃ films, to a concentration of 20 mg/mL. 50 μL is deposited onto the perovskite film by spin coating for 45 seconds at 1000 rpm.

### Electrode Deposition:

Aluminum electrodes were thermally evaporated through a shadow mask with a base pressure of 10⁻⁶ mbar. Typical electrode thicknesses were 80-100 nm (monitored during evaporation with a quartz crystal sensor). The device area was defined by the overlap of the ITO and Al electrodes (1.24 mm²).

### Absorbance and Photoluminescence

Absorbance spectra were collected using either an Agilent 8453 UV-Vis spectrophotometer or a Cary 5000 UV-Vis-NIR spectrophotometer. Photoluminescence spectra were collected using an Ocean Optics QE65000 spectrometer with a 606 nm excitation. Samples were dissolved in hexane. The position of the first excitonic absorbance feature is determined as the peak maximum or as the saddle point of the shoulder for absorbance spectra with less well-defined features.

### Scanning Electron Microscopy

Scanning electron micrographs were collected on a Zeiss Gemini Ultra-55 field emission scanning electron microscope operated at 2.00 kV and using a secondary electron detector. The SEM image in FIG. 4 shows the full view of an ITO/nanocrystal/MAPbI₃/PCBM/Al device cross-section. This device utilized the smallest PbS/CdS core/shell nanocrystals for the HTM. The SEM images in FIG. 5 shows MAPbI₃ films deposited onto 3 different under layers: directly onto ITO, onto a film of the smallest PbS core-only nanocrystals, and onto a film of the smallest PbS/CdS core/shell nanocrystals. The substrate for these films was ITO on glass.

Other embodiments are within the scope of the following claims.

1. A photovoltaic device comprising:
a first charge transporting layer including a plurality of semiconductor nanocrystals including a core and a shell, in contact with a first electrode;
a second charge transporting layer in contact with a second electrode; and
an absorber layer including a perovskite material between the first charge transporting layer and the second charge transporting layer.

2. The photovoltaic device of claim 1, wherein the first charge transporting layer is a hole transport layer.

3. The photovoltaic device of claim 1, wherein the perovskite material includes a lead halide perovskite.

4. The photovoltaic device of claim 3, wherein the core includes a first semiconductor material.

5. The photovoltaic device of claim 4, wherein the first semiconductor material includes PbS.

6. The photovoltaic device of claim 4, wherein the first semiconductor material includes ZnS, ZnSe, ZnTe, CdS, CdSe, CdTe, HgS, HgSe, HgTe, AIN, AlP, AlAs, AlSb, GaN, GaP, GaAs, GaSb, GaSe, InN, InP, InAs, InSb, TIN, TIP, TlAs, TlSb, PbS, PbSe, PbTe, or mixtures thereof.

7. The photovoltaic device of claim 3, wherein the shell includes a second semiconductor material.

8. The photovoltaic device of claim 7, wherein the second semiconductor material includes CdS.

9. The photovoltaic device of claim 7, wherein the second semiconductor material includes ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TlN, TlP, TlAs, TlSb, TlSb, PbS, PbSe, PbTe, or mixtures thereof.

10. The photovoltaic device of claim 1, wherein the perovskite material has the formula (I)
APbX3 (I)
wherein A is an organic or molecular cation and X is a halide ion.

11. The photovoltaic device of claim 10, wherein the A is methyl ammonium.

12. The photovoltaic device of claim 10, wherein the A is ammonium, formamidimium or phosphonium.

13. The photovoltaic device of claim 10, wherein the A is cesium.

14. The photovoltaic device of claim 10, wherein the halide ion is I⁻.

15. The photovoltaic device of claim 10, wherein the halide ion is Br⁻ or Cr.

16. The photovoltaic device of claim 1, wherein the second charge transporting layer is an electron transport layer.

17. The photovoltaic device of claim 16, wherein the electron transport layer includes [6,6]-phenyl-C₆₁-butyric acid methyl ester.

18. The photovoltaic device of claim 1, wherein the first electrode includes indium tin oxide, gallium indium tin oxide, zinc indium tin oxide, titanium nitride, polyaniline, or combination thereof.

19. The photovoltaic device of claim 1, wherein the device further includes a substrate in contact with the first electrode.

20. The photovoltaic device of claim 19, wherein the substrate includes glass, plastic or metal.

21. A method of making a photovoltaic device comprising:
preparing a substrate;
depositing a first electrode on the substrate;
depositing a first charge transporting layer including a plurality of semiconductor nanocrystals including a core and a shell in contact with a first electrode;
depositing an absorber layer including a perovskite material on the first charge transporting layer; and
depositing a second charge transporting layer in contact with the absorber layer.

22.-41. (canceled)
